(19) United States
(12) Patent Application Publication
(10) Pub. No.: US 2024/0375890 A1
(43) Pub. Date: Nov. 14, 2024

(54) Q293851

(71) Applicant: SAMSUNG ELECTRONICS CO., LTD., Suwon-si (KR)

(72) Inventors: Hyunyoung LEE, Suwon-si (KR); Jongseong KO, Suwon-si (KR); Daeyong KIM, Suwon-si (KR); Donghyun KIM, Suwon-si (KR); Jisu KIM, Suwon-si (KR); Pyungkang KIM, Suwon-si (KR); Kihong PARK, Suwon-si (KR); Jungjun PARK, Suwon-si (KR); Jungjoon PARK, Suwon-si (KR); Jooyoung PARK, Suwon-si (KR); Junhyeok PARK, Suwon-si (KR); Hoseok SONG, Suwon-si (KR); Chiho AHN, Suwon-si (KR); Kongwoo LEE, Suwon-si (KR); Chuyoung CHOUNG, Suwon-si (KR); Jeongmin HWANG, Suwon-si (KR)

(73) Assignee: SAMSUNG ELECTRONICS CO., LTD., Suwon-si (KR)

(21) Appl. No.: 18/659,935

(22) Filed: May 9, 2024

(30) Foreign Application Priority Data
May 9, 2023 (KR) 10-2023-0059963
Aug. 22, 2023 (KR) 10-2023-0110131

(51) Int. Cl. B65G 49/00; B25J 11/00; H01L 21/67

(52) U.S. Cl. CPC B65G 49/00; B25J 11/00; H01L 21/6719

(57) ABSTRACT

A maintenance automation equipment includes: a first module comprising: a first support supporting a modular device, a fastening device configured to separate or fasten the modular device, a first inspector comprising a camera, and a first transporter, wherein the fastening device and the first inspector are at one end of the first transporter; a second module comprising: a second support, a cleaning device configured to spray a chemical toward the second support, a second inspector comprising an optical camera, and a second transporter, wherein the cleaning device and the second inspector are at one end of the second transporter; a transport module comprising an inter-module transporter; a first storage module; and a second storage module.

### CROSS-REFERENCE TO RELATED APPLICATION

This application is based on and claims priority under 35 U.S.C. § 119 to Korean Patent Application Nos. 10-2023-0059963, filed on May 9, 2023, and 10-2023-0110131, filed on Aug. 22, 2023, in the Korean Intellectual Property Office, the disclosures of which are incorporated by reference herein in their entireties.

### BACKGROUND

### 1. Field

The disclosure relates to maintenance automation equipment and an automation method of the maintenance automation equipment, and more particularly, to modular maintenance automation equipment and an automation method of the modular maintenance automation equipment.

### 2. Description of Related Art

Semiconductor manufacturing processes tend to be automated for semiconductor productivity and manufacturing efficiency. Periodic maintenance (PM) of semiconductor equipment includes fastening, separation, cleaning of the semiconductor equipment and components included in the semiconductor equipment.

### SUMMARY

Provided is maintenance automation of modular devices included in semiconductor manufacturing equipment.

The problem to be solved by embodiments of the disclosure is not limited to the problem mentioned above, and the other problems could be understood by those of ordinary skill in the art from the description below.

According to an aspect of the disclosure, a maintenance automation equipment includes: a first module comprising: a first support supporting a modular device, a fastening device configured to separate or fasten the modular device, a first inspector comprising a camera, and a first transporter, wherein the fastening device and the first inspector are at one end of the first transporter; a second module comprising: a second support, a cleaning device configured to spray a chemical toward the second support, a second inspector comprising an optical camera, and a second transporter, wherein the cleaning device and the second inspector are at one end of the second transporter; a transport module comprising an inter-module transporter; a first storage module; and a second storage module.

According to an aspect of the disclosure, a maintenance automation method includes: releasing, by a fastening device included in a first module, a coupling portion of a modular device to separate the modular device into a first portion and a used second portion; transporting the first portion to a second module by a transport module; cleaning the first portion by a cleaning device included in the second module; storing the used second portion in a first storage module by the transport module; transporting the cleaned first portion from the second module to the first module by the transport module; transporting an unused second portion stored in a second storage module to the first module by the transport module; and fastening the cleaned first portion and the unused second portion by the fastening device included in the first module, wherein the fastened cleaned first portion and the unused second portion correspond to the modular device.

According to an aspect of the disclosure, a maintenance automation equipment includes: a first module comprising a first support supporting a modular device, a fastening device configured to separate or fasten the modular device, a first inspector comprising a camera, a first transporter having both of the fastening device and the first inspector at one end of the first transporter, and an external entrance port; a second module comprising a second support, a cleaning device configured to spray a chemical toward the second support, a second inspector comprising an optical camera, a second transporter having both of the cleaning device and the second inspector at one end of the second transporter, an internal blocking port, and a blocking partitioning wall; a transport module comprising an inter-module transporter; a first storage module; and a second storage module, wherein the external entrance port is open or closed and is provided to a side surface of the first module facing to an external area, wherein the internal blocking port is open or closed and is provided to a side surface of the second module facing the transport module; wherein the blocking partitioning wall surrounds an outer surface of the second module, and the internal blocking port is on the blocking partitioning wall, wherein the modular device is formed by coupling a reusable first portion and a replaceable second portion, wherein the first storage module is configured to store a plurality of used second portions, wherein the second storage module is configured to store a plurality of unused second portions; wherein the first storage module is adjacent to the second storage module in a lateral direction; wherein the first module and the second module are adjacent to each other in the lateral direction and on the first storage module and the second storage module, respectively; and wherein the transport module is provided to a side facing the first module, the second module, the first storage module, and the second storage module.

### BRIEF DESCRIPTION OF THE DRAWINGS

Embodiments of the disclosure will be more clearly understood from the following detailed description taken in conjunction with the accompanying drawings in which:

FIG. 1 is a perspective view illustrating maintenance automation equipment according to an embodiment;

FIG. 2 is a flowchart illustrating a maintenance automation method according to an embodiment;

FIGS. 3A and 3B are perspective views for describing maintenance automation equipment and a maintenance automation method according to an embodiment;

FIGS. 4A and 4B are perspective views for describing maintenance automation equipment and a maintenance automation method according to an embodiment;

FIGS. 5A and 5B are perspective views for describing maintenance automation equipment and a maintenance automation method according to an embodiment;

FIGS. 6A to 6C are perspective views for describing maintenance automation equipment and a maintenance automation method according to an embodiment;

FIGS. 7A to 7D are perspective views for describing maintenance automation equipment and a maintenance automation method according to an embodiment;

FIGS. 8A and 8B are perspective views for describing maintenance automation equipment and a maintenance automation method according to an embodiment;

FIGS. 9A and 9B are perspective views for describing maintenance automation equipment and a maintenance automation method according to an embodiment; and

FIGS. 10A and 10B are perspective views for describing maintenance automation equipment and a maintenance automation method according to an embodiment.

### DETAILED DESCRIPTION

Hereinafter, embodiments are described in detail with reference to the accompanying drawings. Like reference numerals in the drawings denote like elements, and thus their repetitive description will be omitted.

The term “couple” and the derivatives thereof refer to any direct or indirect communication between two or more elements, whether or not those elements are in physical contact with each other. The terms “transmit”, “receive”, and “communicate” as well as the derivatives thereof encompass both direct and indirect communication. The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

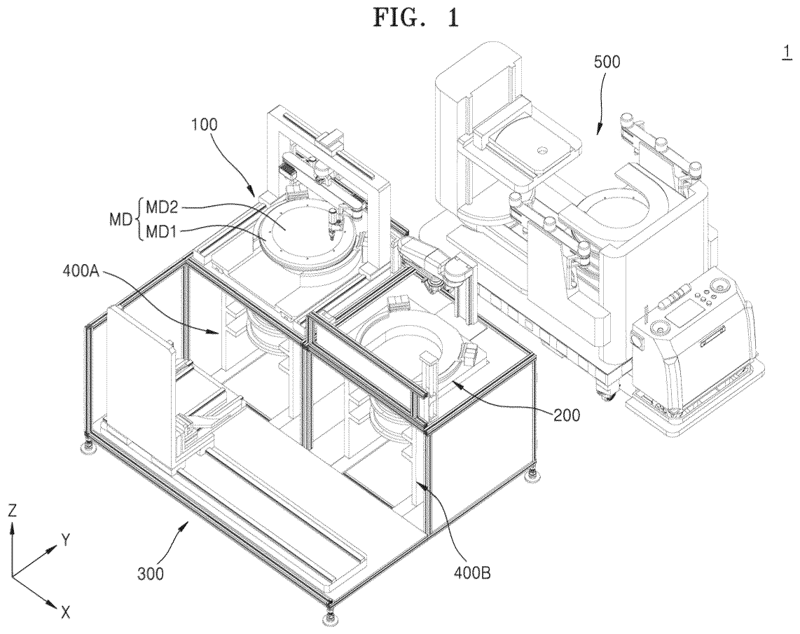

FIG. 1 is a perspective view illustrating maintenance automation equipment 1 according to an embodiment.

Referring to FIG. 1, the maintenance automation equipment 1 according to an embodiment may include a working module 100, a cleaning module 200, a transport module 300, a first storage module 400A, and a second storage module 400B. In the disclosure, the working module 100 may be referred to as a ‘first’ module and the cleaning module 200 may be referred to as a ‘second’ module.

A mobile robot 500 transports a modular device MD from an external area of the maintenance automation equipment 1 to the maintenance automation equipment 1. The modular device MD may be separated into a first portion MD1 and a second portion MD2, and the first portion MD1 and the second portion MD2 may be coupled to be the modular device MD. For example, the modular device MD may be a shower head device, the first portion MD1 may be an alignment jig for a shower head, and the second portion MD2 may be a shower head. In the maintenance automation equipment 1 according to an embodiment, the modular device MD may be divided into two or more portions that can be separated or coupled.

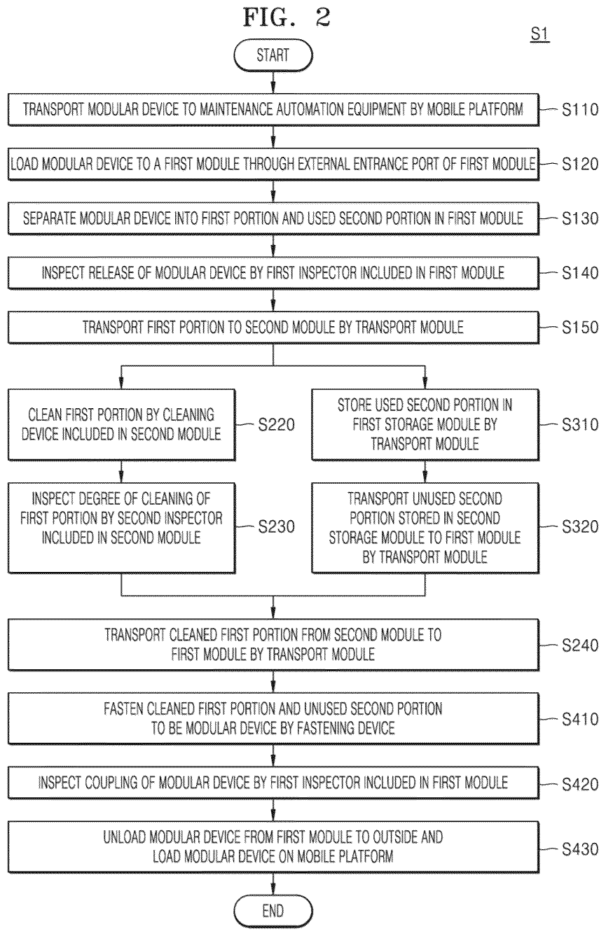

FIG. 2 is a flowchart illustrating a maintenance automation method S1 according to an embodiment. With reference to the flowchart, a particular operating process, each component, and the reference numerals of respective components of the maintenance automation equipment 1 are described using the drawings below.

Referring to FIG. 2, the maintenance automation method S1 according to an embodiment may include transporting a modular device to maintenance automation equipment by a mobile robot (in operation S110), loading the modular device to a first module through an external entrance port of the first module (in operation S120), separating the modular device into a first portion and a used second portion in the first module (in operation S130), inspecting release of the modular device by a first inspector included in the first module (in operation S140), transporting the first portion to a second module by a transport module (in operation S150), cleaning the first portion by a cleaning device included in the second module (in operation S220), inspecting the degree of cleaning of the first portion by a second inspector included in the second module (in operation S230), storing the used second portion in a first storage module by the transport module in (operation S310), transporting an unused second portion stored in a second storage module to the first module by the transport module (in operation S320), transporting the cleaned first portion from the second module to the first module by the transport module (in operation S240), fastening the cleaned first portion and the unused second portion to be the modular device by a fastening device of the first module (in operation S410), inspecting the coupling of the modular device by the first inspector included in the first module (in operation S420), and unloading the modular device from the first module to an external area and loading the modular device on the mobile robot (in operation S430).

In an embodiment, operations S220 of cleaning the first portion and S230 of inspecting the degree of cleaning of the first portion may be performed at the same time as operations S310 of storing the second portion in the first storage module and S320 of transporting the unused second portion to the first module.

The maintenance automation method S1 of the maintenance automation equipment 1, according to an embodiment, may change an order within a properly operating range of the maintenance automation equipment 1. For example, operation S220 of cleaning the first portion and operation S230 of inspecting the degree of cleaning of the first portion may be performed and then operation S310 of storing the second portion in the first storage module and operation S320 of transporting the unused second portion to the first module may be performed. In an embodiment, operation S240 of transporting the cleaned first portion from the second module to the first module by the transport module may be performed and then operation S320 of transporting the unused second portion stored in the second storage module to the first module by the transport module may be performed.

That is, because the maintenance automation equipment 1 according to an embodiment may perform cleaning and inspection and simultaneously perform exchanging an unused second portion, the time taken for maintenance may be reduced, thereby improving maintenance efficiency.

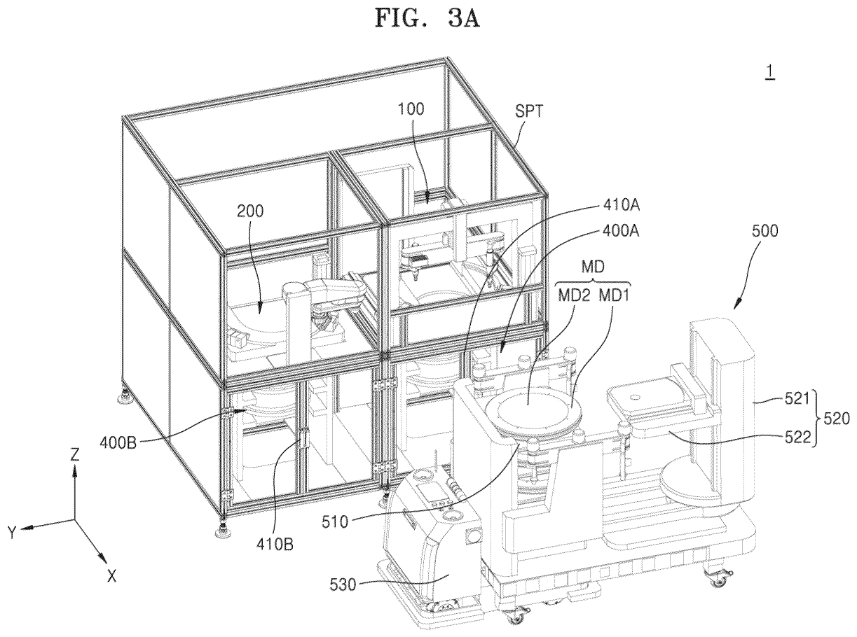

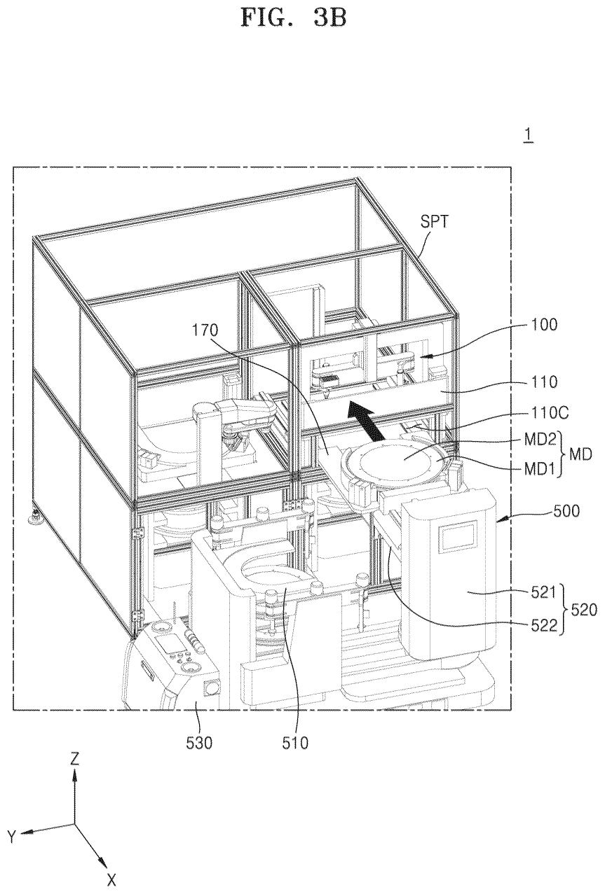

FIGS. 3A and 3B are perspective views for describing the maintenance automation equipment 1 and the maintenance automation method S1 according to an embodiment.

The process shown in FIGS. 3A and 3B may include transporting a used modular device MD from the external area of the maintenance automation equipment 1 to the maintenance automation equipment 1 by the mobile robot 500 and transporting the used modular device MD to the inside of the first module 100 through an external entrance port 110. That is, the process shown in FIGS. 3A and 3B may correspond to operation S110 of transporting a modular device MD to the maintenance automation equipment 1 by the mobile robot 500 and operation S120 of loading the modular device MD to the first module 100 through the external entrance port 110 of the first module 100.

Referring to FIGS. 2, 3A, and 3B, a modular device MD may be separated into a first portion MD1 and a second portion MD2. The mobile robot 500 may include a device storage 510, a device transporter 520, and a moving portion 530. The device storage 510 may be configured to load a plurality of modular devices MD therein. For example, to store circular modular devices MD, the device storage 510 may include a plurality of shelves stacked in the vertical direction, each shelf supporting the outer periphery of a modular device MD.

The device transporter 520 may include a transport robot 521 and an extended arm 522. The extended arm 522 may be provided to a portion of the transport robot 521. The extended arm 522 may take a modular device MD out from the device storage 510 and grip the modular device MD. For example, a gripper may be provided to one end of the extended arm 522. That is, the gripper may grip and take out a modular device MD stored in the device storage 510. The transport robot 521 may be configured to perform a vertical motion, a rotating motion, and a horizontal motion with respect to the mobile robot 500. The transport robot 521 may transport a modular device MD gripped by the extended arm 522 to the inside of the maintenance automation equipment 1.

In the working module 100 of the maintenance automation equipment 1, a partitioning wall SPT may surround the outer periphery of the working module 100. In addition, the partitioning wall SPT may surround at least portions of the outer peripheries of the cleaning module 200, the transport module 300 (see FIG. 1), the first storage module 400A, and the second storage module 400B to be described below. The partitioning wall SPT may separate the maintenance automation equipment 1 from the external area of the maintenance automation equipment 1.

The external entrance port 110 may be provided in the partitioning wall SPT provided to one side surface of the working module 100. The external entrance port 110 may be opened or closed. If the external entrance port 110 is opened, an external entrance space 110C is formed. A first support 170 of the working module 100 to be described below may move outward through the external entrance space 110C. The first support 170 may be located on a rail and configured to extend by moving to an external area of the working module 100. A modular device MD gripped by the extended arm 522 of the mobile robot 500 may be loaded on the first support 170 moved to the external area of the working module 100. For stable transportation of the modular device MD, the extended arm 522 of the mobile robot 500 may be complementarily coupled to the first support 170, and then, the modular device MD may be loaded on the first support 170.

After loading the modular device MD on the first support 170, the extended arm 522 of the mobile robot 500 may be decoupled from the first support 170. Thereafter, the first support 170 may move to the inside of the working module 100. Thereafter, the external entrance port 110 may be closed.

In an embodiment, the modular device MD gripped by the extended arm 522 of the mobile robot 500 may move to the inside of the working module 100. For stable transportation of the modular device MD to the inside of the working module 100, the opened external entrance port 110 may be coupled to a portion of the extended arm 522. For example, the horizontal width of the external entrance space 110C of the opened external entrance port 110 may be substantially the same as the width of the extended arm 522. The extended arm 522 may load the modular device MD on the first support 170 included in the working module 100.

As shown in FIGS. 3A and 3B, the maintenance automation equipment 1 may include the partitioning wall SPT surrounding the maintenance automation equipment 1 to block the maintenance automation equipment 1 from the external area of the maintenance automation equipment 1. However, at least a portion of the partitioning wall SPT adjacent to the mobile robot 500 to transport the modular device MD to the working module 100 may include a transparent material. In embodiments of the disclosure, a portion of the partitioning wall SPT through which the modular device MD is transported to the working module 100 may be referred to as a front partitioning wall. That is, at least a portion of the front partitioning wall may include a transparent material. The transparent material may include glass, a polymer resin, or the like. The transparent material of at least a portion of the partitioning wall SPT is to see the status and operating state of the working module 100, the cleaning module 200, the transport module 300, the first storage module 400A, and the second storage module 400B with the naked eye.

In addition, a door, which can be opened or closed, may be provided to at least a portion of the partitioning wall SPT adjacent to the first storage module 400A and the second storage module 400B. As shown in FIG. 3A, a first open/close (open or close) door 410A may be provided on the partitioning wall SPT adjacent to the first storage module 400A and a second open/close door 410B may be provided on the partitioning wall SPT adjacent to the second storage module 400B. A second portion MD2 to be stored in the first storage module 400A may pass through the first open/close door 410A, and a second portion MD2 stored in the second storage module 400B may pass through the second open/close door 410B.

For example, the first storage module 400A and the second storage module 400B may be adjacent to each other in a lateral direction. The transport module 300 may face the first storage module 400A and the second storage module 400B. The working module 100 and the cleaning module 200 may be stacked on the first storage module 400A and the second storage module 400B, respectively. Likewise, the transport module 300 may face the working module 100 and the cleaning module 200. For example, if a long time is taken for cleaning, two or more cleaning modules 200 may be included in the maintenance automation equipment 1 to increase the efficiency of a maintenance process. If there is an additional cleaning module 200, the additional cleaning module 200 may be arranged by considering the shape of a space in which the maintenance automation equipment 1 is to be arranged, the transport efficiency of the transport module 300, and the like.

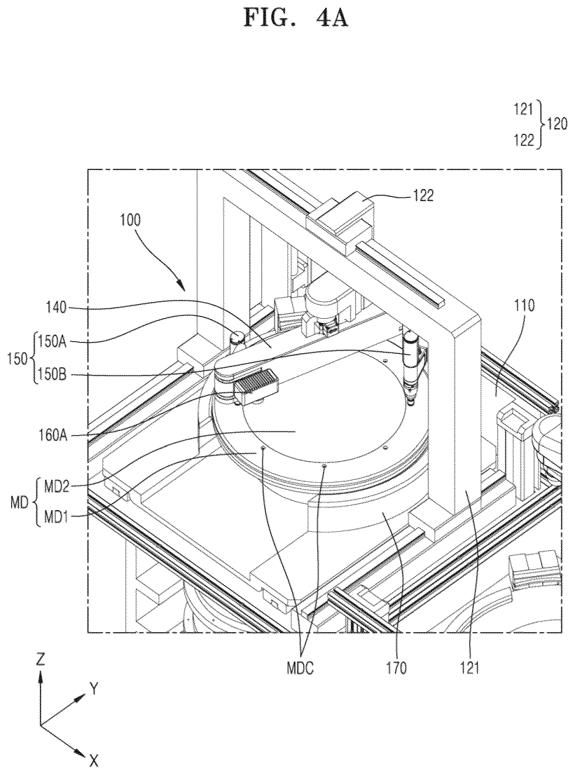

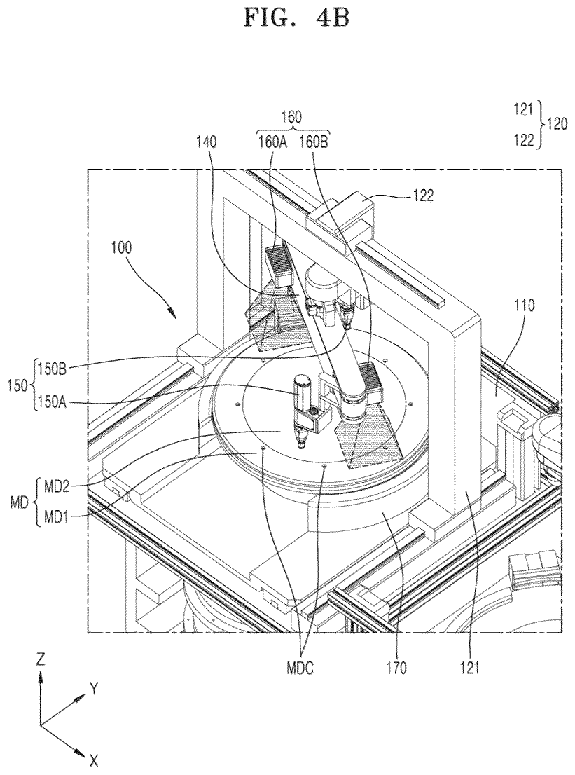

FIGS. 4A and 4B are perspective views for describing the maintenance automation equipment 1 and the maintenance automation method S1 according to an embodiment.

Referring to FIGS. 2, 4A, and 4B, a modular device MD may be separated into a first portion MD1 and a used second portion MD2 by the first module 100 in operation S130, and a first inspector 160 included in the first module 100 may inspect release of the modular device MD in operation S140.

A modular device fastener MDC of the modular device MD loaded on the first support 170 by the extended arm 522 may be released by a fastening device 150. Once the modular device MD is released, the modular device MD may be separated into the first portion MD1 and the second portion MD2. For example, the first portion MD1 may be coupled to the second portion MD2 by a fastening member, such as a screw, provided to the modular device fastener MDC. In an embodiment, the modular device MD may be separated into the first portion MD1 and the second portion MD2 by releasing the fastening member, such as a screw, provided to the modular device fastener MDC. The modular device MD may include at least one modular device fastener MDC.

A device rod 140 may be provided to one end of a first transporter 120. The first transporter 120 may be configured such that the device rod 140 to which the fastening device 150 and the first inspector 160 are provided horizontally moves, vertically moves, and rotates in the working module 100. For example, the first transporter 120 may include a first rail transporter 121 on a transport rail to be movable in a second horizontal direction (the Y direction) and a second rail transporter 122 configured to move in a first horizontal direction (the X direction) that is perpendicular to the second horizontal direction (the Y direction) along a rail formed on the first rail transporter 121. The device rod 140 may be connected to a lower end of the second rail transporter 122, and the second rail transporter 122 may be configured such that the device rod 140 rotates and vertically moves with respect to the second rail transporter 122.

The fastening device 150 may be provided to the device rod 140. The fastening device 150 may include a force/torque sensor. In an embodiment, a first fastening device 150A may be provided to one end of the device rod 140. In addition, a second fastening device 150B may be provided to the other end of the device rod 140. The first fastening device 150A and the second fastening device 150B may be at opposite sides of the device rod 140.

The fastening device 150 may release the fastening member of the modular device fastener MDC provided to the modular device MD. Alternatively, the fastening device 150 may fix the fastening member of the modular device fastener MDC provided to the modular device MD.

A work inspector (the first inspector) 160 may be provided to the device rod 140. In an embodiment, a first work inspector 160A may be provided to the one end of the device rod 140. In addition, a second work inspector 160B may be provided to the other end of the device rod 140. The first work inspector 160A and the second work inspector 160B may be respectively at opposite sides of the device rod 140. In addition, the first work inspector 160A may be provided to the opposite side of the one end of the device rod 140 where the first fastening device 150A is arranged, and the second work inspector 160B may be provided to the opposite side of the other end of the device rod 140 where the second fastening device 150B is arranged.

The work inspector 160 may include an optical camera, a light source, and the like. The work inspector 160 may identify a fastening or release state of the modular device fastener MDC and whether work on the modular device fastener MDC ends. For example, for the modular device MD loaded on the first support 170, the work inspector 160 may identify the state of the fastening member of the modular device fastener MDC. After the fastening device 150 releases the fastening member of the modular device fastener MDC, the work inspector 160 may identify whether the fastening member of the modular device fastener MDC has been released. In this case, the first transporter 120 may properly move, and then, the device rod 140 may rotate with respect to (under, in, near) the first transporter 120 such that the work inspector 160 identifies the state of a plurality of modular device fasteners MDC provided to the modular device MD.

In related art, in a case that the modular device fastener MDC of the modular device MD is fastened or released by a worker, the lifespan of the modular device MD may be reduced more than expected due to a non-uniform work.

In contrast, in the maintenance automation equipment 1 according to an embodiment, a plurality of fastening devices 150 may be provided to be able to quickly perform a work, and an external force applied to the fastening member of the modular device fastener MDC may be precisely measured using the force/torque sensor included in the fastening device 150 to minimize damage to the fastening member and the modular device MD. In addition, a repeated same work may be performed by an automation device to accurately perform the work. Therefore, the time consumed for maintenance may be reduced, errors due to a worker may be minimized, and the efficiency and reliability of the maintenance may be improved.

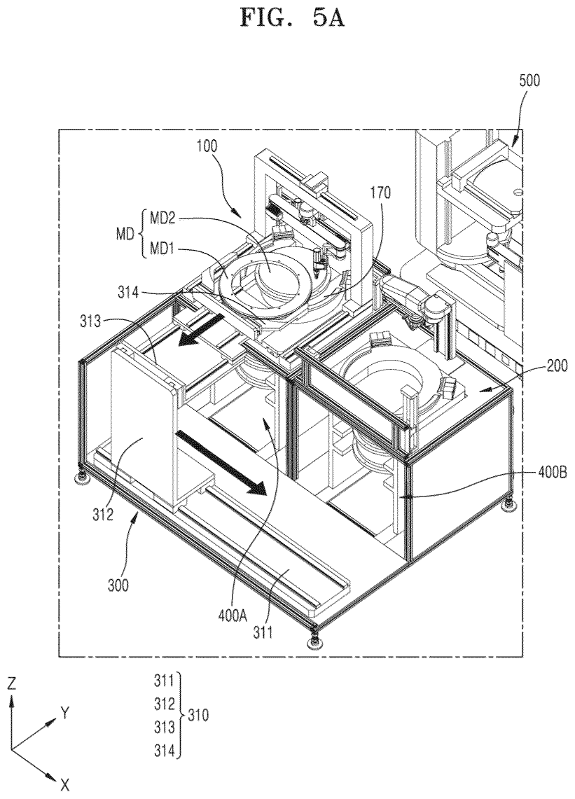

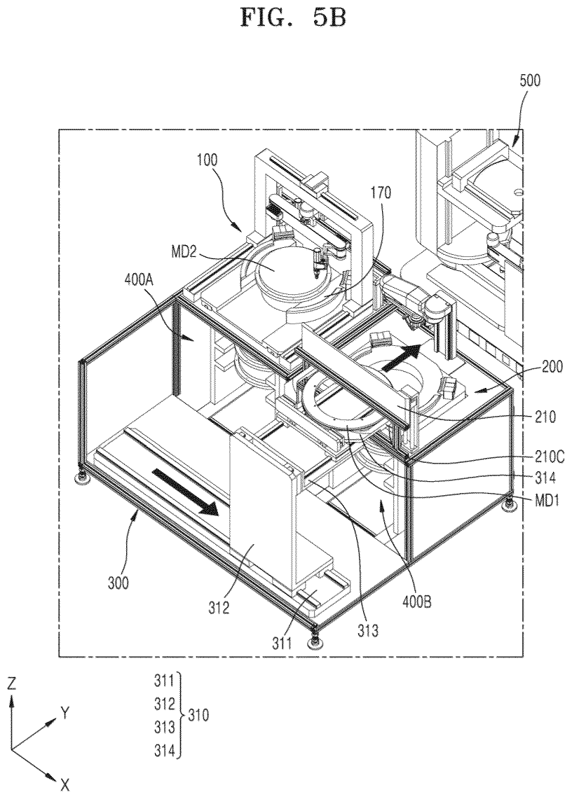

FIGS. 5A and 5B are perspective views for describing the maintenance automation equipment 1 and the maintenance automation method S1 according to an embodiment.

Referring to FIGS. 2, 5A, and 5B, the first portion MD1 may be transported to the second module (cleaning module) 200 by the transport module 300 in operation S210. That is, the first portion MD1 may be transported to the cleaning module 200 by the transport module 300.

The transport module 300 may include an inter-module transporter 310. The inter-module transporter 310 may perform a rotating motion and a three-axial translation motion in the first horizontal direction (the X direction), the second horizontal direction (the Y direction), and the vertical direction (the Z direction) that is perpendicular to the first horizontal direction (the X direction) and the second horizontal direction (the Y direction).

For example, the inter-module transporter 310 may include a horizontal rail 311 extending in a first direction, a horizontal mover 312 moving in the first direction along the horizontal rail 311, a stretchable portion 313 stretching in a second direction on the horizontal mover 312, and a transporter gripper 314 provided to one end of the stretchable portion 313 and configured to selectively grip the first portion MD1, the second portion MD2, and the modular device MD.

The transporter gripper 314 may grip the first portion MD1 or the second portion MD2 and transport the same to another module. For example, as shown in FIG. 5A, the transporter gripper 314 may grip the first portion MD1, then the stretchable portion 313 may retract, and the horizontal mover 312 adjacent to the working module 100 may move in a lateral direction. As shown in FIG. 5B, when the horizontal mover 312 is located adjacent to the cleaning module 200, the stretchable portion 313 may stretch, and the first portion MD1 gripped by the transporter gripper 314 may be loaded on the cleaning module 200.

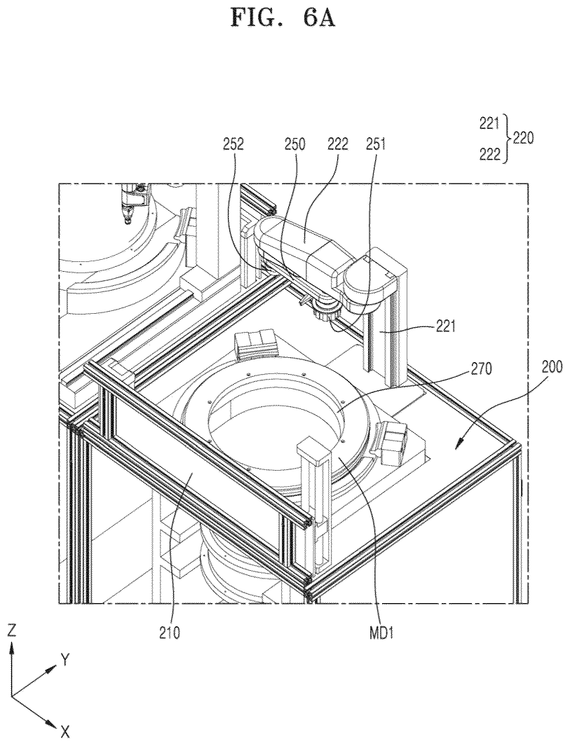

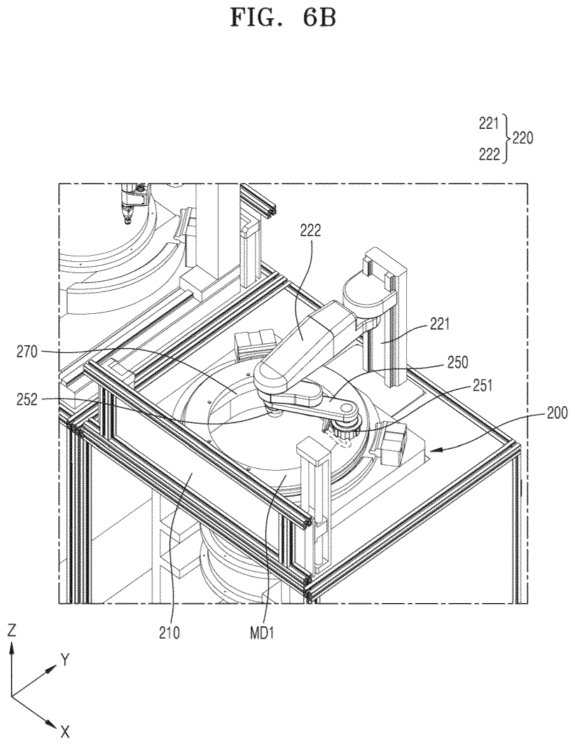

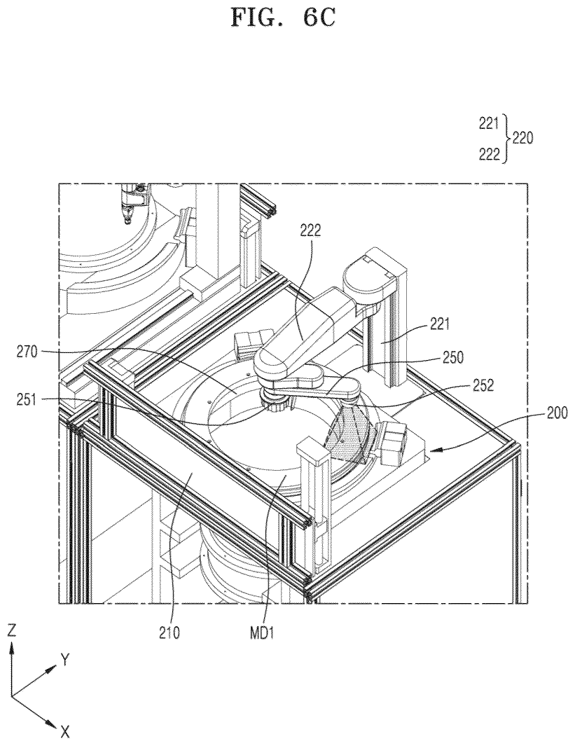

The cleaning module 200 to be described below may include an internal blocking port 210, a second transporter 220 (see FIG. 6A), a cleaning rod 250 (see FIG. 6A), a cleaning device 251 (see FIG. 6A) provided to one end of the cleaning rod 250 (see FIG. 6A), a cleaning inspector 252 (see FIG. 6A) provided to the other end of the cleaning rod 250 (see FIG. 6A), and a second support 270 (see FIG. 6A). A detailed configuration of the cleaning module 200 is described below.

The internal blocking port 210 may be opened or closed. As shown in FIG. 5B, when the internal blocking port 210 is opened, the stretchable portion 313 of the transport module 300 may stretch such that the transporter gripper 314 having gripped the first portion MD1 may move to the inside of the cleaning module 200 through a blocking port opening hole 210C.

FIGS. 6A to 6C are perspective views for describing the maintenance automation equipment 1 and the maintenance automation method S1 according to an embodiment.

The process shown in FIGS. 6A to 6C may include cleaning the first portion MD1 by the cleaning device 251 included in the cleaning module 200 and inspecting the degree of cleaning of the first portion MD1 by the cleaning inspector 252 included in the cleaning module 200. That is, the process shown in FIGS. 6A to 6C may correspond to operation S220 of cleaning the first portion by the cleaning device included in the second module and operation S230 of inspecting the degree of cleaning of the first portion by the second inspector included in the second module in FIG. 2.

Referring to FIGS. 2 and 6A to 6C, the cleaning module 200 may include the internal blocking port 210, the second transporter 220, the cleaning rod 250, the cleaning device 251 provided to the one end of the cleaning rod 250, the cleaning inspector 252 provided to the other end of the cleaning rod 250, and the second support 270.

The first portion MD1 may be loaded on the second support 270 included in the cleaning module 200. When the first portion MD1 is loaded on the second support 270, the transporter gripper 314 (e.g., FIG. 5B) of the transport module 300 (e.g., FIG. 5B) described above may move to an external area of the cleaning module 200, and the internal blocking port 210 may be closed. In some embodiments, as shown in FIGS. 3A and 4B, the partitioning wall SPT in FIG. 3B may surround the side surfaces of the cleaning module 200. As described below, the first portion MD1 may be cleaned by the cleaning device 251 in the cleaning module 200, but because a cleaning liquid may spatter to another component during the cleaning to thereby contaminate or remain in the component, the side surfaces of the cleaning module 200 may be surrounded and blocked by the partitioning wall SPT (e.g., FIG. 3B). However, the internal blocking port 210 may be provided to a portion of the partitioning wall SPT (e.g., FIG. 3B) between the transport module 300 (e.g., FIG. 5B) and the cleaning module 200.

The second transporter 220 may be configured to perform a rotating motion and a translation motion in the first horizontal direction (the X direction), the second horizontal direction (the Y direction), and the vertical direction (the Z direction) such that the cleaning device 251 cleans the first portion MD1. For example, the second transporter 220 may include a vertical pillar portion 221 having a vertical rail provided to the surface of the vertical pillar portion 221, and a second robot arm 222 capable of vertically moving along the vertical rail provided to the vertical pillar portion 221 and configured to rotate with respect to the vertical pillar portion 221. The cleaning rod 250 may be provided to one end of the second robot arm 222, and the cleaning rod 250 may be configured to rotate with respect to the one end of the second robot arm 222.

In an embodiment, the cleaning device 251 may clean the first portion MD1 of the shape, as shown in FIG. 6B, by moving along the shape of the first portion MD1 while the cleaning rod 250 is rotating with respect to the one end of the second robot arm 222.

The cleaning device 251 may clean the first portion MD1 by spraying a chemical toward the first portion MD1. For example, the chemical may include at least one of materials among water, ethanol, ultrapure water, deionized water, nitrogen, or carbon dioxide.

As shown in FIG. 6C, after cleaning is performed by the cleaning device 251 in the cleaning module 200, the degree of cleaning of the first portion MD1 may be inspected by the cleaning inspector 252 provided to the cleaning rod 250. For example, the cleaning inspector 252 may include a camera and a light source. The cleaning inspector 252 may move along the shape of the first portion MD1 and inspect the cleaning state of the first portion MD1.

The cleaning state may be evaluated by the cleaning inspector 252 included in the cleaning module 200. If the cleaning state is good, the first portion MD1 may be transported to the working module 100 by the transport module 300 as described below. Otherwise, the cleaning state may be evaluated by the cleaning inspector 252. If the cleaning state is not good, a cleaning operation may be performed again by the cleaning device 251 in the cleaning module 200.

In the related art, when the modular device MD is cleaned by a worker, the worker may be exposed to the chemical which may be harmful to the human body. In addition, when cleaning is performed by a worker, the quality of the cleaning may not be uniform, or it may be substantially difficult to quantitatively evaluate a cleaning state after the cleaning.

In contrast, the maintenance automation equipment 1 according to an embodiment is unmanned and automated to clean the modular device MD. Therefore, the quality of cleaning may be constantly maintained, and because the state of the cleaning after the cleaning is evaluated by the cleaning inspector 252, the cleaning state may be quantitatively evaluated. Therefore, the safety, reliability, and efficiency of a cleaning process on an object may be improved.

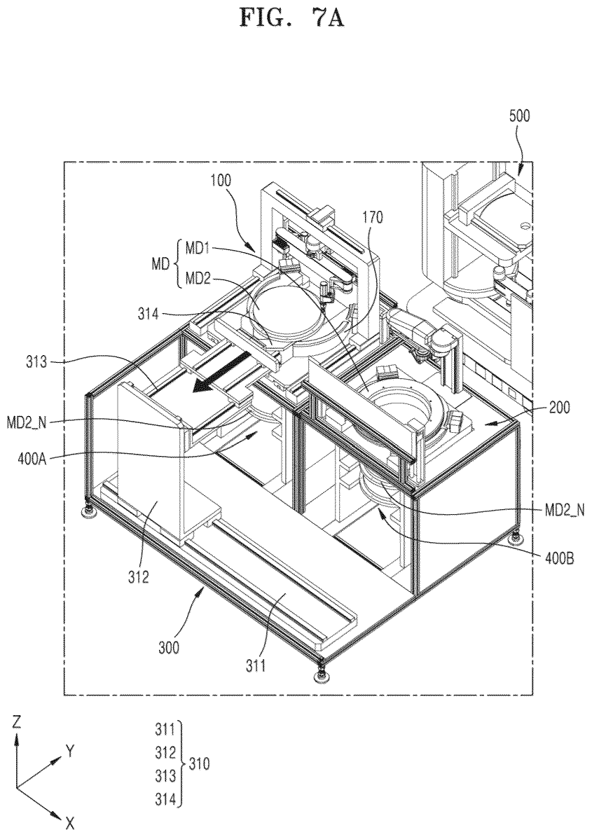

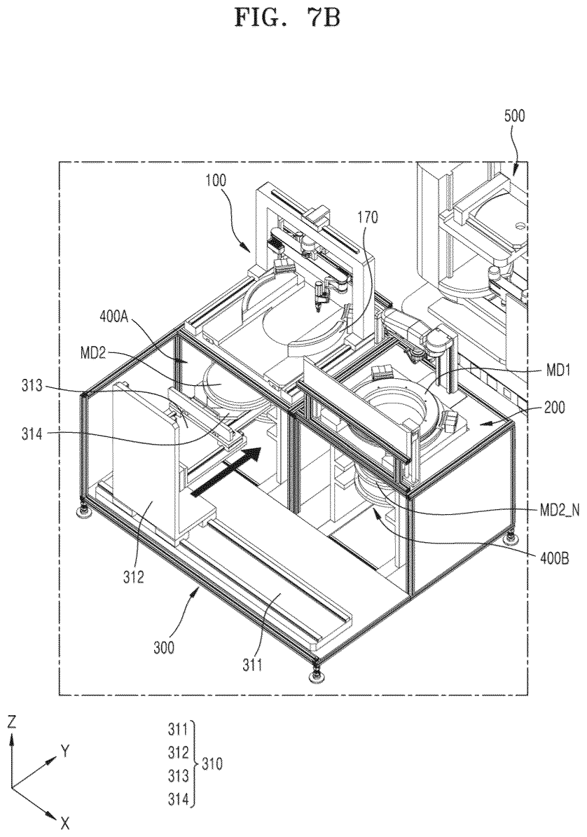

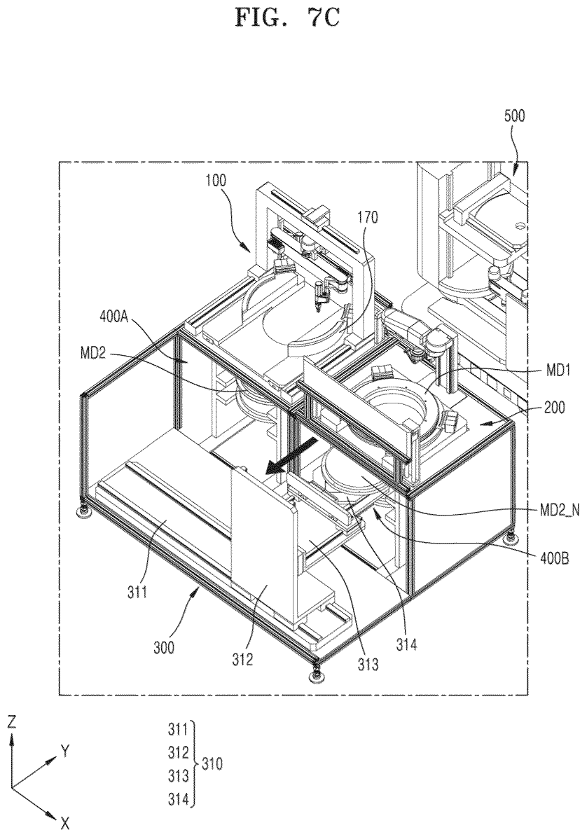

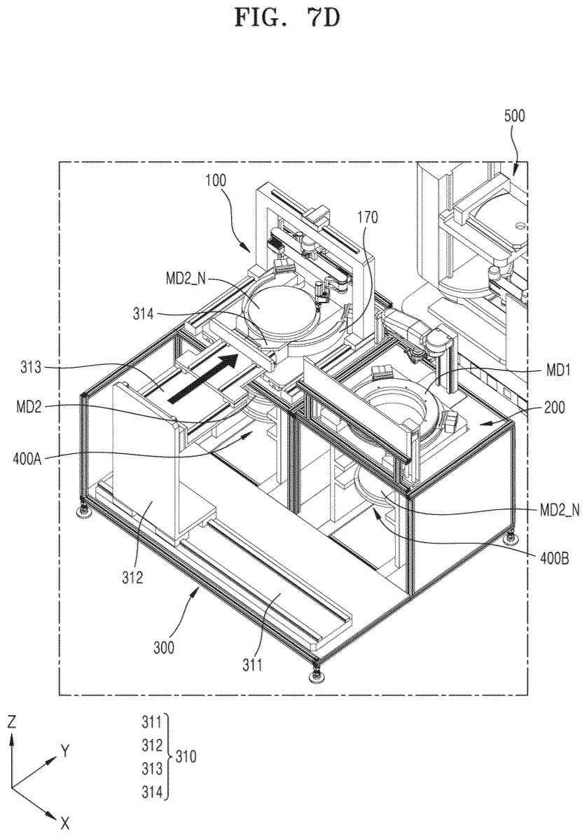

FIGS. 7A to 7D are perspective views for describing the maintenance automation equipment 1 and the maintenance automation method S1 according to an embodiment.

The process shown in FIGS. 7A to 7D may correspond to operating S310 of storing the used second portion MD2 in the first storage module 400A by the transport module 300 and operation S320 of transporting an unused second portion MD2_N stored in the second storage module 400B to the first module 100 by the transport module 300.

Referring to FIGS. 2, 7A, and 7B, the used second portion MD2 loaded on the first support 170 of the working module 100 may be transported to the first storage module 400A by the transport module 300. The used second portion MD2 indicates a second portion MD2 of a modular device MD used in other equipment.

For example, the transporter gripper 314 of the transport module 300 may grip the used second portion MD2 loaded on the first support 170 of the working module 100 and move from the working module 100 toward the transport module 300. The inter-module transporter 310 may move toward the first storage module 400A in which the used second portion MD2 is to be stored, among the first storage module 400A and the second storage module 400B. When the transporter gripper 314 reaches the front of the first storage module 400A, the stretchable portion 313 may stretch toward the first storage module 400A. The transporter gripper 314 may store the gripped used second portion MD2 on a shelf included in the first storage module 400A. In addition, the first storage module 400A may include a plurality of shelves on which a plurality of used second portions MD2 are to be stored.

Referring to FIGS. 2, 7C, and 7D, the transport module 300 may transport an unused second portion MD2_N from the second storage module 400B to the working module 100.

For example, the unused second portion MD2_N stored on a shelf of the second storage module 400B may be gripped by the transporter gripper 314 of the transport module 300. The transporter gripper 314 having gripped the unused second portion MD2_N may move from the second storage module 400B toward the transport module 300. The inter-module transporter 310 may move toward the working module 100. When the transporter gripper 314 reaches the front of the working module 100, the stretchable portion 313 may stretch to the inside of the working module 100. The transporter gripper 314 may load the gripped unused second portion MD2_N on the first support 170 provided to the inside of the working module 100. In addition, the second storage module 400B may include a plurality of shelves on which a plurality of unused second portions MD2_N are to be stored.

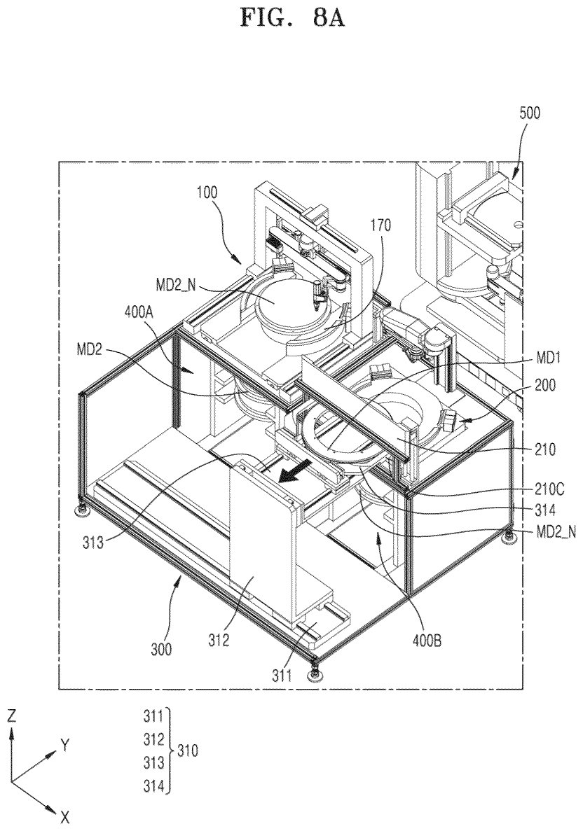

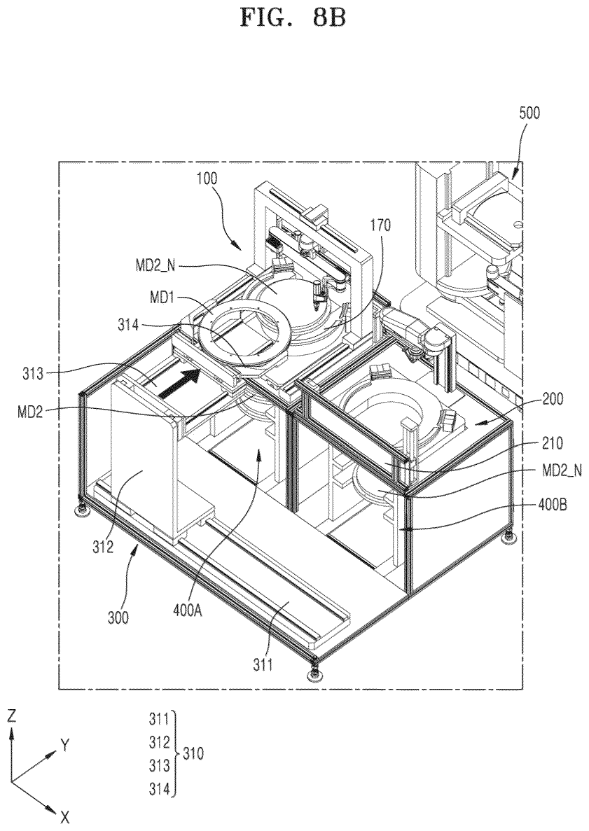

FIGS. 8A and 8B are perspective views for describing the maintenance automation equipment 1 and the maintenance automation method S1 according to an embodiment.

The process shown in FIGS. 8A and 8B may correspond to operation S240 of transporting the cleaned first portion MD1 from the second module 200 to the first module 100 by the transport module 300.

Referring to FIGS. 2, 8A, and 8B, the transport module 300 may transport the cleaned first portion MD1 from the cleaning module 200 to the working module 100. For example, the transporter gripper 314 of the transport module 300 may grip the cleaned first portion MD1 in the cleaning module 200. The gripped first portion MD1 may move toward the transport module 300 when the stretchable portion 313 retracts. The inter-module transporter 310 may be at the front of the working module 100, and the gripped first portion MD1 may be transported to the inside of the working module 100. The gripped first portion MD1 may be loaded on the first support 170 of the working module 100, and the transporter gripper 314 may retract from the inside of the working module 100.

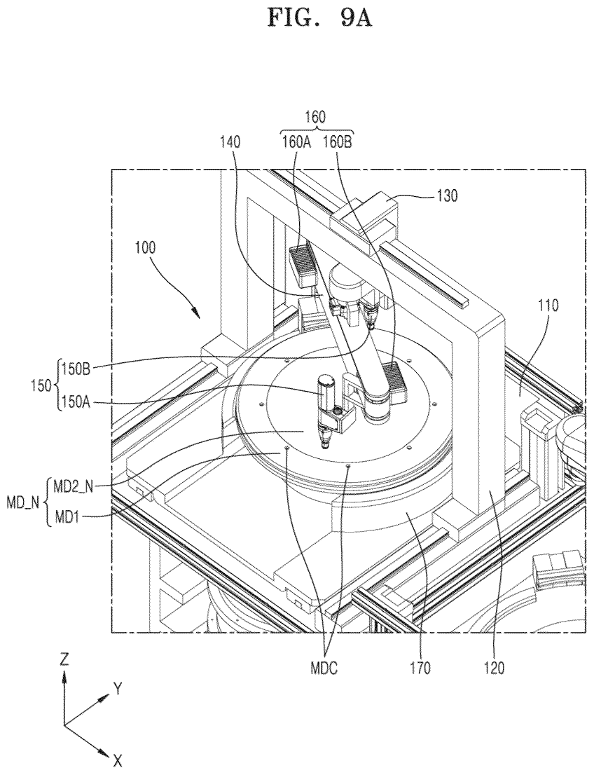

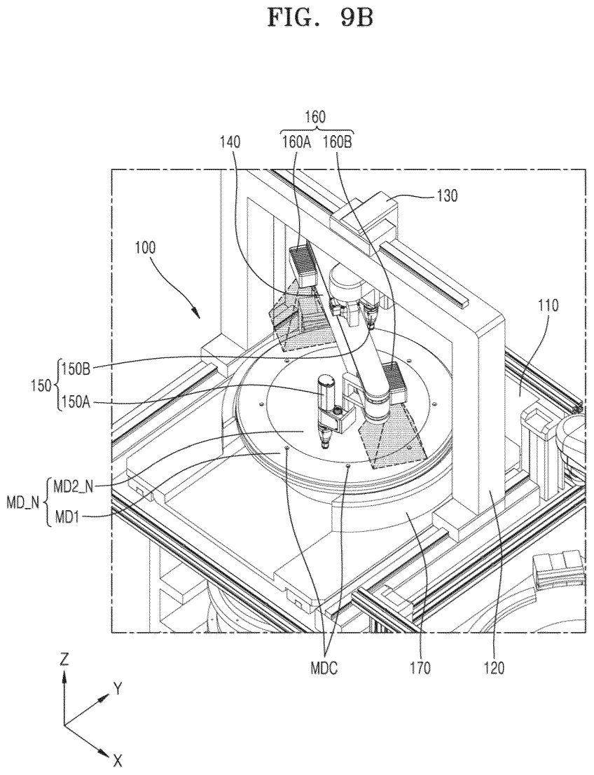

FIGS. 9A and 9B are perspective views for describing the maintenance automation equipment 1 and the maintenance automation method S1 according to an embodiment.

The process shown in FIGS. 9A and 9B may correspond to operation S410 of fastening the cleaned first portion MD1 and the unused second portion MD2_N to be an unused modular device MD_N by the fastening device 150 of the first module 100 and operation S420 of inspecting the coupling of the unused modular device MD_N by the first inspector 160 included in the first module 100.

Referring to FIGS. 9A and 9B, the cleaned first portion MD1 and the unused second portion MD2_N may be fastened by the fastening device 150 to be assembled as the unused modular device MD_N. Thereafter, the fastening state of the modular device fastener MDC of the unused modular device MD_N may be inspected by the first inspector 160. A description of the fastening and release of the modular device fastener MDC by the fastening device 150 and inspection of a fastened state and a released state is the same as the description made with reference to FIGS. 4A and 4B and is thus not repeated herein.

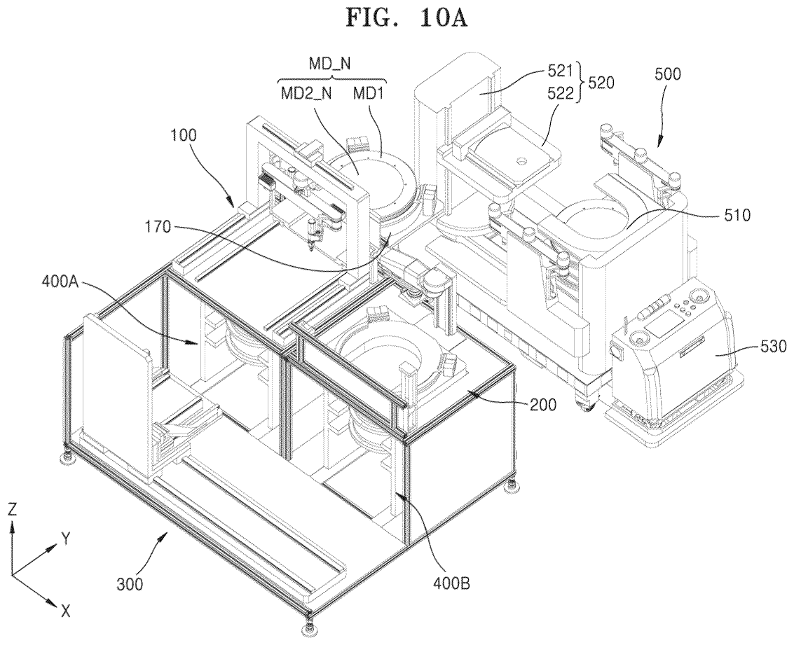

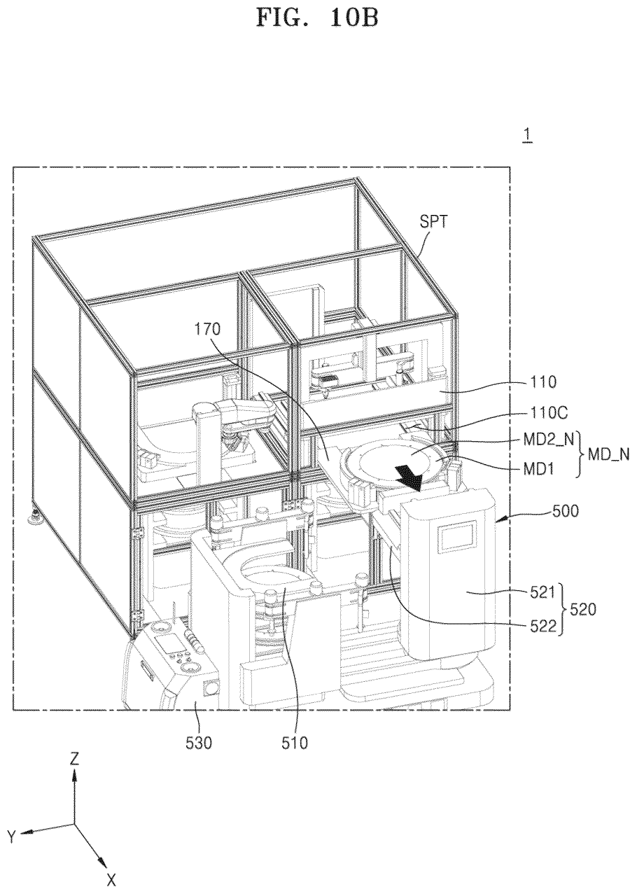

FIGS. 10A and 10B are perspective views for describing the maintenance automation equipment 1 and the maintenance automation method S1 according to an embodiment.

The process shown in FIGS. 10A and 10B may correspond to operation S430 of unloading the modular device MD from the first module 100 to an external area of the first module 100 and loading the modular device MD on the mobile robot 500.

Referring to FIGS. 10A and 10B, the unused modular device MD_N may be unloaded from the working module 100 through the opened external entrance port 110. This process has a reverse order of the process described above with reference to FIGS. 3A and 3B, and thus, a repeated description of the process is omitted herein.

In the maintenance automation equipment 1 according to an embodiment, the arrangement of the working module 100, the cleaning module 200, the transport module 300, the first storage module 400A, and the second storage module 400B may be changed in accordance with circumstances.

The mobile robot 500 having stored one or more unused modular devices MD_N in the device storage 510 through a series of processes may move to equipment in which an unused modular device MD_N is to be mounted.

Because the maintenance automation equipment 1 according to an embodiment automates the entire maintenance process on a modular device, a working time is reduced more than that of manual maintenance by a worker, and thus, a stop time of process equipment from which a modular device has been removed during a maintenance process may be reduced. In addition, because a modular device is fastened, released, and cleaned based on quantitative measurements of a sensor, the possibility that a maintenance process is performed again may be reduced. Therefore, the productivity and reliability of equipment for which maintenance is to be performed may be improved according to an increase in the efficiency of a maintenance process.

While the disclosure has been particularly shown and described with reference to embodiments of the disclosure, it will be understood that various changes in form and details may be made therein without departing from the spirit and scope of the following claims.

What is claimed is:

1. A maintenance automation equipment comprising:
a first module comprising:
a first support supporting a modular device,
a fastening device configured to separate or fasten the modular device,
a first inspector comprising a camera, and
a first transporter, wherein the fastening device and the first inspector are at one end of the first transporter;
a second module comprising:
a second support,
a cleaning device configured to spray a chemical toward the second support,
a second inspector comprising an optical camera, and
a second transporter, wherein the cleaning device and the second inspector are at one end of the second transporter;
a transport module comprising an inter-module transporter;
a first storage module; and
a second storage module.

2. The maintenance automation equipment of claim 1, wherein the first module further comprises an external entrance port,
wherein the second module further comprises an internal blocking port,
wherein the external entrance port is open or closed, the external entrance port being provided to a side surface of the first module facing an external area of the first module, and
wherein the internal blocking port is open or closed, the internal blocking port being provided to a side surface of the second module facing the transport module.

3. The maintenance automation equipment of claim 2, wherein the inter-module transporter comprises:
a robot arm configured to stretch, in one direction, from the transport module and configured to move in a three-axial direction including:
a first horizontal direction,
a second horizontal direction perpendicular to the first horizontal direction, and
a vertical direction perpendicular to the first horizontal direction and the second horizontal direction, and
a gripper provided to one end of the robot arm.

4. The maintenance automation equipment of claim 2, wherein the second module further comprises a blocking partitioning wall that surrounds the outer surface of the second module, and
wherein the internal blocking port is on the blocking partitioning wall.

5. The maintenance automation equipment of claim 2, wherein the modular device is formed by coupling a reusable first portion with a replaceable second portion,
wherein the first storage module is configured to store a plurality of used second portions, and
wherein the second storage module is configured to store a plurality of unused second portions.

6. The maintenance automation equipment of claim 2, wherein one end of the first transporter includes a first rod being adjacent to and being separated from the first support,
wherein the first rod is configured to rotate near the first transporter on a horizontal surface,
wherein the modular device includes a coupling portion,
wherein the fastening device is configured to fasten or release the coupling portion included in the modular device,
wherein the fastening device and the first inspector are at one end of the first rod and are adjacent to each other, and
wherein the fastening device is on one side of the first rod and the first inspector is on an opposite side of the first rod.

7. The maintenance automation equipment of claim 2, wherein a second rod is provided to one end of the second transporter,
wherein the cleaning device is provided to one end of the second rod,
wherein the second inspector is provided to the other end of the second rod, and
wherein the second rod is configured to rotate near the second transporter.

8. The maintenance automation equipment of claim 5, wherein the first storage module is adjacent to the second storage module in a lateral direction,
wherein the first module and the second module are adjacent to each other in the lateral direction and on the first storage module and the second storage module, respectively, and
wherein the transport module is provided to a surface facing the first module, the second module, the first storage module, and the second storage module.

9. The maintenance automation equipment of claim 2, wherein, in a case that the external entrance port is opened, the first support is configured to horizontally move by stretching and protruding to the external area of the first module, and
wherein the first support is configured to be coupled to one end of a device transporter of a mobile robot.

10. The maintenance automation equipment of claim 2, wherein the chemical comprises at least one of ethanol, ultrapure water, deionized water, nitrogen, or carbon dioxide.

11. The maintenance automation equipment of claim 5, wherein the modular device includes a shower head device,
wherein the reusable first portion includes an alignment jig for a shower head, and
wherein the replaceable second portion includes the shower head.

12. The maintenance automation equipment of claim 4, wherein the first storage module further comprises a first open/close door at an opposite side to an arrangement direction of the transport module, and
wherein the second storage module further comprises a second open/close door at the opposite side to the arrangement direction of the transport module.

13. The maintenance automation equipment of claim 12, wherein the first module and the second module further comprise a front partitioning wall including a transparent material on one side surface of the first module and one side surface of the second module, which are the opposite side of the arrangement direction of the transport module,
wherein the external entrance port is provided on the front partitioning wall, and
wherein portions of the first open/close door and the second open/close door include a transparent material.

14. A maintenance automation equipment comprising:
a first module comprising:
a first support supporting a modular device,
a fastening device configured to separate or fasten the modular device,
a first inspector comprising a camera, and
a first transporter, wherein the fastening device and the first inspector are at one end of the first transporter;
a second module comprising:
a second support,
a cleaning device configured to spray a chemical toward the second support,
a second inspector comprising an optical camera, and
a second transporter, wherein the cleaning device and the second inspector are at one end of the second transporter;
a transport module comprising an inter-module transporter;
a first storage module; and
a second storage module,
wherein the modular device is formed by coupling a reusable first portion with a replaceable second portion,
wherein the first storage module is configured to store a plurality of used second portions, and
wherein the second storage module is configured to store a plurality of unused second portions.

15. The maintenance automation equipment of claim 14, wherein the first inspector included in the first module inspect coupling and release of the coupling portion of the modular device, and
Wherein the second inspector included in the second module inspect a degree of cleaning of the first portion.

16. The maintenance automation equipment of claim 15, wherein one end of the first transporter includes a first rod being adjacent to and being separated from the first support,
wherein the first rod is configured to rotate near the first transporter on a horizontal surface,
wherein the modular device includes a coupling portion,
wherein the fastening device is configured to fasten or release the coupling portion included in the modular device,
wherein the fastening device and the first inspector are at one end of the first rod and are adjacent to each other, and
wherein the fastening device is on one side of the first rod and the first inspector is on an opposite side of the first rod.

17. The maintenance automation equipment of claim 16, wherein a second rod is provided to one end of the second transporter,
wherein the cleaning device is provided to one end of the second rod,
wherein the second inspector is provided to the other end of the second rod, and
wherein the second rod is configured to rotate near the second transporter.

18. The maintenance automation equipment of claim 17, wherein the first storage module is adjacent to the second storage module in a lateral direction,
wherein the first module and the second module are adjacent to each other in the lateral direction and on the first storage module and the second storage module, respectively, and
wherein the transport module is provided to a surface facing the first module, the second module, the first storage module, and the second storage module.

19. A maintenance automation equipment comprising:
a first module comprising a first support supporting a modular device, a fastening device configured to separate or fasten the modular device, a first inspector comprising a camera, a first transporter having both of the fastening device and the first inspector at one end of the first transporter, and an external entrance port;
a second module comprising a second support, a cleaning device configured to spray a chemical toward the second support, a second inspector comprising an optical camera, a second transporter having both of the cleaning device and the second inspector at one end of the second transporter, an internal blocking port, and a blocking partitioning wall;
a transport module comprising an inter-module transporter;
a first storage module; and
a second storage module,
wherein the external entrance port is open or closed and is provided to a side surface of the first module facing to an external area,
wherein the internal blocking port is open or closed and is provided to a side surface of the second module facing the transport module;
wherein the blocking partitioning wall surrounds an outer surface of the second module, and the internal blocking port is on the blocking partitioning wall,
wherein the modular device is formed by coupling a reusable first portion and a replaceable second portion,
wherein the first storage module is configured to store a plurality of used second portions,
wherein the second storage module is configured to store a plurality of unused second portions;
wherein the first storage module is adjacent to the second storage module in a lateral direction;
wherein the first module and the second module are adjacent to each other in the lateral direction and on the first storage module and the second storage module, respectively; and
wherein the transport module is provided to a side facing the first module, the second module, the first storage module, and the second storage module.

20. The maintenance automation equipment of claim 19, wherein the chemical comprises at least one of ethanol, ultrapure water, deionized water, nitrogen, or carbon dioxide;
wherein the first transporter comprises a first rod provided at one end of the first transporter, the first rod being adjacent to and being separated from the first support;
wherein the first rod is configured to rotate near the first transporter on a horizontal surface;
wherein both of the fastening device configured to fasten or release a coupling portion included in the modular device and the first inspector are at one end of the first rod,
wherein the fastening device and the first inspector are be adjacent to the first rod and are provided to opposite sides of the first rod,
wherein a second rod is provided to one end of the second transporter,
wherein the cleaning device is provided to one end of the second rod, and the second inspector is provided to the other end of the second rod,
wherein the second rod is configured to rotate near the second transporter,
wherein, in a case that the external entrance port is opened, the first support is configured to horizontally move by stretching and protruding to an external area of the first module;
wherein the first support is configured to be coupled to one end of a device transporter of a mobile robot, and
wherein the modular device includes a shower head device, the first portion includes an alignment jig for a shower head, and the second portion includes the shower head.
